(19) United States
(12) Patent Application Publication
(10) Pub. No.: US 2026/0134815 A1
(43) Pub. Date: May 14, 2026

(54) SHIFT REGISTER, DISPLAY PANEL AND DISPLAY APPARATUS

(71) Applicant: Xiamen Tianma Display Technology Co., Ltd., Xiamen (CN)

(72) Inventors: Xuehuan Feng, Xiamen (CN); Yana Gao, Xiamen (CN); Xingyao Zhou, Xiamen (CN); Zhiqiang Xia, Xiamen (CN); Kang Yang, Xiamen (CN); Lei Wang, Xiamen (CN)

(73) Assignee: Xiamen Tianma Display Technology Co., Ltd., Xiamen (CN)

(21) Appl. No.: 19/438,762

(22) Filed: Jan. 2, 2026

(30) Foreign Application Priority Data
May 28, 2025 (CN) 202510697581.7

(51) Int. Cl. G09G 3/20; G11C 19/28

(52) U.S. Cl. CPC G09G 3/2092; G09G 2310/0286; G11C 19/287

(57) ABSTRACT

A shift register includes shift units. The shift unit includes: first output module for writing signal of first high potential line into output terminal when first node is at high level; second output module for writing signal of low potential line into output terminal when second node is at high level; first control module for writing signal to first node; and second control module for writing signal to second node. The first control module includes first unit and first transistor; first unit is configured to write signal of input terminal into third node in response to signal provided by first clock terminal; gate of first transistor is electrically connected to second high potential line. The second high potential line provides second high potential signal, and voltage value of second high potential signal is smaller than voltage value of high level in signal provided by input terminal.

### CROSS-REFERENCE TO RELATED APPLICATIONS

The present application claims priority to Chinese Application No. 202510697581.7 with the application title of “SHIFT REGISTER, DISPLAY PANEL AND DISPLAY APPARATUS”, filed on May 28, 2025, the content of which is incorporated herein by reference in its entirety.

### TECHNICAL FIELD

The present disclosure relates to the field of display technologies, specifically a shift register, a display panel and a display apparatus.

### BACKGROUND

In the display panel, the shift register is configured to provide a driving signal to a pixel circuit, enabling the pixel circuit to transmit a driving current to the light-emitting element under the action of the driving signal, thereby driving the light-emitting element to emit light. However, the circuit structure of the shift register in the related art has the electric leakage issue of the nodes, thereby causing abnormal output and affecting display.

### SUMMARY

An aspect of the present disclosure provides a shift register that includes cascaded shift units. The shift units are configured to output a driving signal, with an effective level being a high level. One of the shift units includes: a first output module, configured to write a signal of a first high potential line into an output terminal when a first node is at a high level; a second output module, configured to write a signal of a low potential line into the output terminal when a second node is at a high level; a first control module, configured to write a signal to the first node; and a second control module, configured to write a signal to the second node. The first control module includes a first unit and a first transistor; the first unit is configured to write a signal of an input terminal into a third node in response to a signal provided by a first clock terminal; the first transistor is electrically connected between the third node and the first node, and a gate of the first transistor is electrically connected to a second high potential line, wherein the second high potential line provides a second high potential signal, and a voltage value of the second high potential signal is smaller than a voltage value of a high level in a signal provided by the input terminal.

Another aspect of the present disclosure provides a display panel. The display panel includes a pixel circuit and at least one shift register electrically connected to the pixel circuit. One of the at least one shift register includes cascaded shift units that are configured to output a driving signal with an effective level being a high level. One of the shift units includes: a first output module, configured to write a signal of a first high potential line into an output terminal when a first node is at a high level; a second output module, configured to write a signal of a low potential line into the output terminal when a second node is at a high level; a first control module, configured to write a signal to the first node; and a second control module, configured to write a signal to the second node. The first control module includes a first unit and a first transistor; the first unit is configured to write a signal of an input terminal into a third node in response to a signal provided by a first clock terminal; the first transistor is electrically connected between the third node and the first node, and a gate of the first transistor is electrically connected to a second high potential line, wherein the second high potential line provides a second high potential signal, and a voltage value of the second high potential signal is smaller than a voltage value of a high level in a signal provided by the input terminal.

Another aspect of the present disclosure provides a display apparatus. The display apparatus includes a display panel. The display panel includes a pixel circuit and at least one shift register electrically connected to the pixel circuit. One of the at least one shift register includes cascaded shift units that are configured to output a driving signal with an effective level being a high level. One of the shift units includes: a first output module, configured to write a signal of a first high potential line into an output terminal when a first node is at a high level; a second output module, configured to write a signal of a low potential line into the output terminal when a second node is at a high level; a first control module, configured to write a signal to the first node; and a second control module, configured to write a signal to the second node. The first control module includes a first unit and a first transistor; the first unit is configured to write a signal of an input terminal into a third node in response to a signal provided by a first clock terminal; the first transistor is electrically connected between the third node and the first node, and a gate of the first transistor is electrically connected to a second high potential line, wherein the second high potential line provides a second high potential signal, and a voltage value of the second high potential signal is smaller than a voltage value of a high level in a signal provided by the input terminal.

### BRIEF DESCRIPTION OF DRAWINGS

In order to more clearly illustrate technical solutions of embodiments of the present disclosure, the accompanying drawings used in the embodiments are briefly described below. It should be noted that the accompanying drawings described below are merely some embodiments of the present disclosure, and other drawings may be obtained by those skilled in the art according to these drawings.

FIG. 1 is a structural schematic diagram of a shift register in the related art.

FIG. 2 is a timing sequence in the related art.

FIG. 3 is a structural schematic diagram of a shift register according to some embodiments of the present disclosure.

FIG. 4 is a schematic diagram of a circuit structure of a shift unit according to some embodiments of the present disclosure.

FIG. 5 is a timing sequence corresponding to FIG. 4 according to some embodiments of the present disclosure.

FIG. 6 is a schematic diagram of a circuit structure of a shift unit according to some embodiments of the present disclosure.

FIG. 7 is a schematic diagram of a circuit structure of a shift unit according to some embodiments of the present disclosure.

FIG. 8 is a timing sequence corresponding to FIG. 7 according to some embodiments of the present disclosure.

FIG. 9 is a schematic diagram of a circuit structure of a shift unit according to some embodiments of the present disclosure.

FIG. 10 is a schematic diagram of a circuit structure of a shift unit according to some embodiments of the present disclosure.

FIG. 11 is a schematic diagram of a circuit structure of a shift unit according to some embodiments of the present disclosure.

FIG. 12 is a schematic diagram of a circuit structure of a shift unit according to some embodiments of the present disclosure.

FIG. 13 is a schematic diagram of a circuit structure of a shift unit according to some embodiments of the present disclosure.

FIG. 14 is a schematic diagram of a circuit structure of a shift unit according to some embodiments of the present disclosure.

FIG. 15 is a schematic diagram of a circuit structure of a shift unit according to some embodiments of the present disclosure.

FIG. 16 is a schematic diagram of a circuit structure of a shift unit according to some embodiments of the present disclosure.

FIG. 17 is a schematic diagram of a circuit structure of a shift unit according to some embodiments of the present disclosure.

FIG. 18 is a structural schematic diagram of a display panel according to some embodiments of the present disclosure.

FIG. 19 is a schematic diagram of a circuit structure of a pixel circuit according to some embodiments of the present disclosure.

FIG. 20 is a structural schematic diagram of a display panel according to some embodiments of the present disclosure.

FIG. 21 is a structural schematic diagram of a display apparatus according to some embodiments of the present disclosure.

### DESCRIPTION OF EMBODIMENTS

In order to better understand technical solutions of the present disclosure, the embodiments of the present disclosure are described in details with reference to the drawings.

It should be understood that the described embodiments are merely part of the embodiments of the present disclosure rather than all of the embodiments. All other embodiments obtained by those skilled in the art without paying creative labor shall fall into the protection scope of the present disclosure.

The terms used in the embodiments of the present disclosure are merely for the purpose of describing specific embodiment, rather than limiting the present disclosure. The terms “a,” “an,” “the,” and “said” in a singular form in the embodiment of the present disclosure and the attached claims are also intended to include plural forms thereof, unless noted otherwise.

It should be understood that the term “and/or” used in the context of the present disclosure is to describe a correlation relation of related objects, indicating that there may be three relations, e.g., A and/or B may indicate only A, both A and B, and only B. In addition, the symbol “/” in the context generally indicates that the relation between the objects in front and at the back of “/” is an “or” relationship.

The present disclosure relates to a shift register, which includes a plurality of cascaded shift units. Each of the shift units is configured to output a driving signal with an effective level being a high level. One N-type transistor in a pixel circuit is conducted under the action of the high level of the driving signal, thereby enabling the pixel circuit to perform corresponding operation.

Before describing the technical solutions provided by the embodiments of the present disclosure, the present disclosure first describes issues existed in the shift register in the related art.

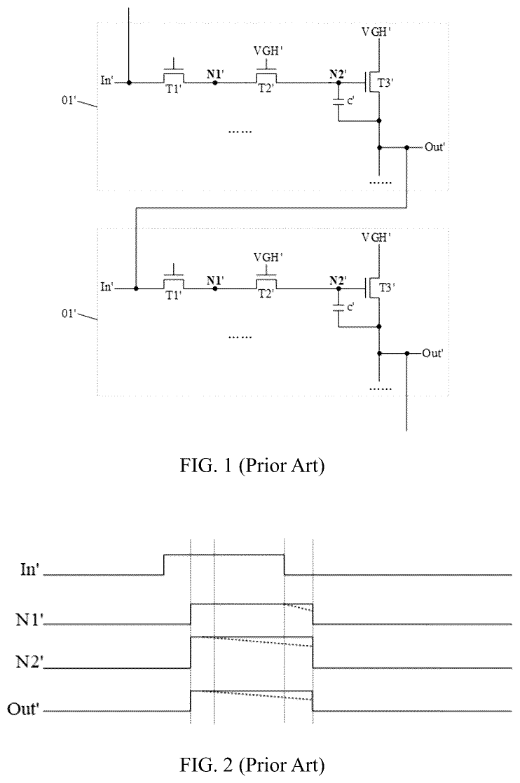

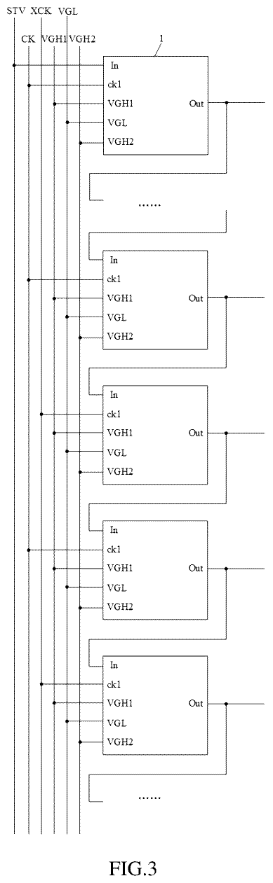

FIG. 1 is a structural schematic diagram of a shift register in the related art, while FIG. 2 is a timing sequence in the related art. In some embodiments, the shift register includes a plurality of cascaded shift units 01′, which may include a transistor T1′, a transistor T2′, and a transistor T3′.

The transistor T1′ may be electrically connected between an input terminal In′ and a node N1′. The transistor T2′ may be electrically connected between the node N1′ and a node N2′. The transistor T3′ may be electrically connected between a high potential line VGH′ and an output terminal Out′, and the gate thereof may be electrically connected to the node N2′.

In the process of controlling the output terminal Out′ to output a high level, the transistor T1′ may be turned on. In some embodiments, a high level provided by the input terminal In′ is written into the node N1′. The high level provided by the transistor T1′ is written into the node N2′ via the turned-on transistor T2′, thereby enabling the transistor T3′ to be further turned on under the action of the high level provided by the node N2′, writing the high level provided by the high potential line VGH′ into the output terminal Out′.

In two adjacent stages of shift units 01′, an input signal provided by the input terminal In′ of a next-stage shift unit 01′may be the same as an output signal provided by the output terminal Out′ of a previous-stage shift unit 01′. For example, the input terminal In′ of the latter shift unit 01′is directly electrically connected to the output terminal Out′ of the former shift unit 01′. It can thus be understood that the high level voltage value provided by the input terminal In′ of the latter shift unit 01′may be equal to the high level voltage value output by the output terminal Out′ of the former shift unit 01′, and is further equal to a voltage v₀′ provided by the high potential line VGH′.

Furthermore, combined with the process of the output terminal Out′ outputting a high level, when the output terminal Out′ outputs a high level, a potential of node N1′ may be the high level voltage v₀′ provided by the input terminal In′, and the potential of node N2′ may be greater than or equal to the high level voltage v₀′ provided by the input terminal In′. For example, when a capacitor c′ is connected between the node N2′ and the output terminal Out′, when a signal output by the output terminal Out′ switches from low to high, the capacitor c′ may couple and increase the potential of node N2′ to v₁′, where v₁′ is greater than v₀′. Since the gate of transistor T2′ receives a potential of v₀′, the gate-source voltage of transistor T2′ is 0.

As a result, when a threshold voltage of transistor T2′ is relatively small, the transistor T2′ may be prone to off-state leakage current. In some embodiments, a leakage path will form from the node N2′ and the node N1′ to the input terminal In′, causing the node N2′ to leak electricity, thereby leading abnormal output of the output terminal Out′. In other words, this circuit structure allows a very narrow range of process fluctuations for the threshold voltage of the transistor, thereby increasing process difficulty and reducing the feasibility of mass production.

In view of this, embodiments of the present disclosure provide a shift register, which can effectively alleviate the above electric leakage issue based on the circuit design of the shift unit in the shift register.

FIG. 3 is a structural schematic diagram of a shift register according to some embodiments of the present disclosure. According to the exemplary embodiment shown in FIG. 3, the shift register includes a plurality of cascaded shift units 1, and the shift units 1 are configured to output a driving signal with an effective level being a high level.

In some embodiments, the shift unit 1 has an input terminal In, a first clock terminal ck1 and an output terminal Out. The input terminal In of a first stage shift unit 1 is electrically connected to a start signal line STV. In two adjacent stages of shift units 1, a signal input by the input terminal In of a next-stage shift unit 1 is the same as a signal output by the output terminal Out of a previous-stage shift unit 1. Exemplarily, the input terminal In of the next-stage shift unit 1 may be directly electrically connected to the output terminal Out of the previous-stage shift unit 1. Additionally, in two adjacent stages of shift units 1, the first clock terminal ck1 of one shift unit 1 is electrically connected to the first clock signal line CK, while the first clock terminal ck1 of the other shift unit 1 is electrically connected to the second clock signal line XCK.

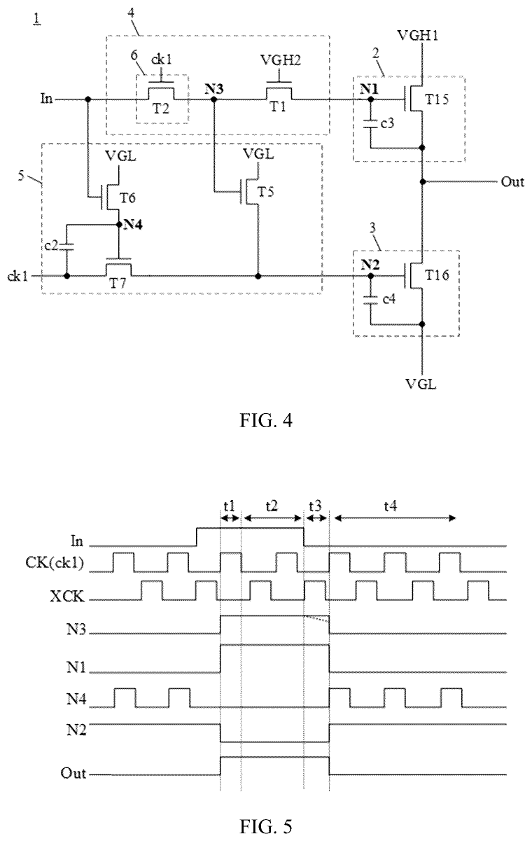

FIG. 4 is a schematic diagram of a circuit structure of a shift unit 1 according to some embodiments of the present disclosure, FIG. 5 is a timing sequence corresponding to FIG. 4 according to some embodiments of the present disclosure. According to the exemplary embodiments shown in FIG. 4 and FIG. 5, the shift unit 1 includes a first output module 2, a second output module 3, a first control module 4 and a second control module 5.

In some embodiments, the first output module 2 is configured to write the signal of the first high potential line VGH1 into the output terminal Out when the first node N1 is at the high level. The second output module 3 is configured to write the signal of the low potential line VGL into the output terminal Out when the second node N2 is at the high level.

In some embodiments, the first control module 4 is configured to write a signal to the first node N1, and the second control module 5 is configured to write a signal to the second node N2.

In some embodiments, the first control module 4 includes a first unit 6 and a first transistor T1. The first unit 6 writes the signal of the input terminal In into the third node N3 in response to the signal provided by the first clock terminal ck1. The first transistor T1 is electrically connected between the third node N3 and the first node N1. The first transistor T1 may be an N-type transistor. A gate of the first transistor T1 is electrically connected to the second high potential line VGH2. The second high potential line VGH2 provides a second high potential signal. A voltage value of the second high potential signal is less than the high level voltage in the signal provided by the input terminal In.

In some embodiments, the first high potential line VGH1 provides a first high potential signal. In combination with the above analysis, it can be seen that the high level voltage in the signal provided by the input terminal In is equal to the voltage value of the first high potential signal, and then the voltage value of the second high potential signal is less than the voltage value of the first high potential signal. The voltage value of the low level in the signal provided by the input terminal In is equal to the voltage value of the signal of the low potential line VGL.

In an embodiment of the present disclosure, a voltage value of the second high potential signal is v₁, and the high level voltage in the signal provided by the input terminal In is v₂. In the process that the output terminal Out outputs the high level, the first unit 6 writes the high level provided by the input terminal In into the third node N3 in response to the signal provided by the first clock terminal ck1. The high level of the third node N3 is further written into the first node N1 through the turned-on first transistor T1, enabling the first output module 2 to output the high level to the output terminal Out in response to the high level of the first node N1.

During this process, the voltage of the third node N3 becomes v₂ after a high level is written into the third node N3, while the voltage of the first node N1 becomes greater than or equal to v₂ after a high level is written into the first node N1. For example, referring to FIG. 2, when the third capacitor c3 is connected between the first node N1 and the output terminal Out, the potential of the first node N1 is coupled and raised up to v₃ (where v₃>v₂) by the third capacitor c3 as the signal output from the output terminal Out transitions from low to high. It can be seen that after the first output module 2 starts outputting a high level, the potentials at the two electrodes of the first transistor T1 are v₂ and v₃, respectively. Since both v₂ and v₃ are greater than the gate potential v₁, the gate-source voltage of the first transistor T1 becomes negative and far lower than its threshold voltage. As a result, the first transistor T1 is completely turned off, electric leakage is effectively prevented from the first node N1 through the path of the first transistor T1, thereby stabilizing the potential of the first node N1, and thus enabling the first output module 2 to output a high level stably.

In summary, in some embodiments of the present disclosure, the gate of the first transistor T1 receives the second high potential signal. By making the voltage value of the second high potential signal less than the high level voltage in the signal provided by the input terminal In, after the first output module 2 outputs the high level, the first transistor T1 can be in a fully off state, thereby preventing an issue of off-state leakage current, thereby effectively preventing electric leakage of the first node N1, and thus improving the stability of the signal output by the shift unit 1.

From another perspective, after the first output module 2 outputs a high level, the gate-source voltage of the first transistor T1 is negative, which further increases the difference between the gate-source voltage of the first transistor T1 and the threshold voltage. Even if the threshold voltage of the first transistor T1 fluctuates due to factors such as process precision or environmental factors, resulting in a slightly smaller actual value, the first transistor T1 can still be ensured to be in a fully off state. By adopting the technical solution provided by the embodiments of the present disclosure, the process fluctuation range allowed by the threshold voltage of the transistor in the shift unit 1 can be expanded, which greatly improves the feasibility of mass production of the circuit.

The operation process of the shift unit 1 is described below with reference to FIG. 4 and FIG. 5.

In some embodiments, in the first period t1, the input terminal In provides a high level. The first clock terminal ck1 provides a high level. The first unit 6 is turned on in response to the high level of the first clock terminal ck1 to write the high level of the input terminal In into the third node N3. The high level of the third node N3 is written into the first node N1 via the turned on first transistor T1. The first output module 2 outputs a high level to the output terminal Out in response to the high level of the first node N1. Meanwhile, the second control module 5 writes a low level to the second node N2. In this period, after the output terminal Out outputs a high level, the first transistor T1 is in a completely off state.

In some embodiments, in the second period t2, the input terminal In continuously provides a high level. The third node N3 and the first node N1 maintain a high level, and the output terminal Out continuously outputs the high level. In this period, the first transistor T1 is still in the off state.

In some embodiments, in the third period t3, the input terminal In provides a low level. The first clock terminal ck1 provides a low level. The first unit 6 is turned off. The third node N3 and the first node N1 maintain a high level, and the output terminal Out continuously outputs a high level. In this period, the first transistor T1 is still in the off state.

In some embodiments, in the fourth period t4, the input terminal In provides a low level. The first clock terminal ck1 provides a high level. The first unit 6 is turned on, and the low level provided by the input terminal In is written into the third node N3. Then the gate-source voltage of the first transistor T1 becomes greater than its threshold voltage, the first transistor T1 is turned on, the low level of the third node N3 is written into the first node N1, and the first output module 2 is turned off. In this period, the second control module 5 writes a high level to the second node N2, and the second output module 3 outputs a low level to the output terminal Out in response to the high level of the second node N2.

In some embodiments, 1V≤v₂−v₁≤3V. Under the condition that v₂ is constant, the voltage difference between v₂ and v₁ is less than or equal to 3V, which can avoid the situation where the first transistor T1 fails to conduct normally due to excessively low v₂. Meanwhile, the voltage difference between v₂ and v₁ also satisfies being greater than or equal to 1V, thereby ensuring that the gate-source voltage of the first transistor T1 is sufficiently negative after the first output module 2 starts to output the high level and the gate-source voltage of the first transistor T1 is far smaller than the threshold voltage thereof, and thus making the first transistor T1 be turned off more thoroughly.

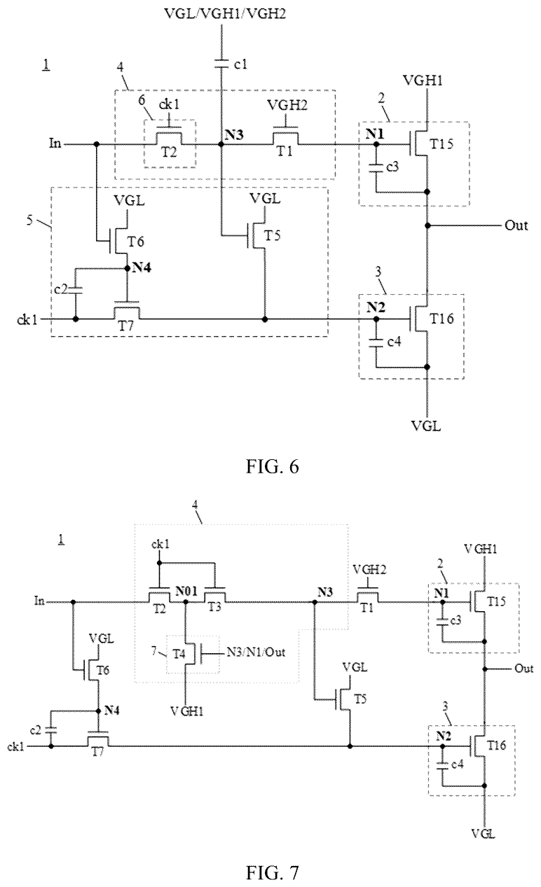

FIG. 6 is a schematic diagram of a circuit structure of a shift unit 1 according to some embodiments of the present disclosure. In some embodiments, as shown in FIG. 6, the shift unit 1 further includes a first capacitor c1. A first terminal of the first capacitor c1 is electrically connected to the third node N3. A second terminal of the first capacitor c1 receives a fixed potential signal.

The first unit 6 may be electrically connected to the first clock terminal ck1 and the third node N3 respectively, and may be connected to the first capacitor c1 at the third node N3, thereby stabilizing the voltage of the third node N3 by using the first capacitor c1, improving the anti-coupling capability of the third node N3, and thus reducing the influence of the voltage jump of a first clock signal on the potential of the third node N3.

Further, referring to embodiment illustrated in FIG. 6, the second terminal of the first capacitor c1 may be electrically connected to the low potential line VGL, the first high potential line VGH1 or the second high potential line VGH2. These signal lines are constant voltage lines that the shift unit 1 originally needs to be connected to. Fixed potential signals are transmitted on the constant voltage lines. The first capacitor c1 is connected to these signal lines, which eliminates the need to add other constant voltage lines for the first capacitor c1, thus simplifying the structure.

In some embodiments, referring to FIG. 4 again, the first unit 6 includes a second transistor T2, which may be the N-type transistor. The second transistor T2 is electrically connected between the input terminal In and the third node N3, and a gate of the second transistor T2 is electrically connected to the first clock terminal ck1. When the first clock terminal ck1 provides a high level, the second transistor T2 is turned on, so as to write the signal of the input terminal In into the third node N3.

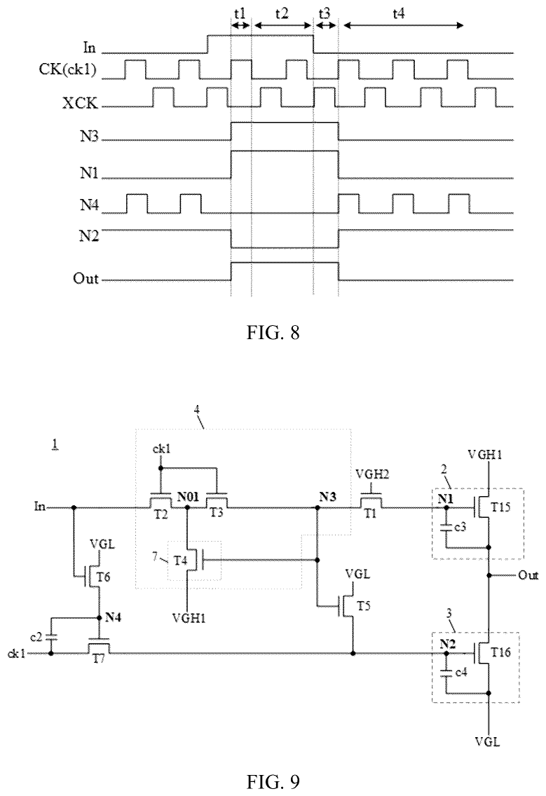

FIG. 7 is a schematic diagram of a circuit structure of a shift unit 1 according to some embodiments of the present disclosure. FIG. 8 is a timing sequence corresponding to FIG. 7. In some embodiments, such as those shown in FIG. 7 and FIG. 8, the second transistor T2 is electrically connected to the third node N3 through the third transistor T3. The third transistor T3 may be the N-type transistor. A gate of the third transistor T3 is electrically connected to a gate of the second transistor T2, and a first intermediate node N01 is provided between the second transistor T2 and the third transistor T3.

In some embodiments, the first control module 4 further includes a second unit 7, which writes a high level to the first intermediate node N01 in response to the first signal. The third transistor T3 and the second unit 7 are configured to prevent the electric leakage of the third node N3. For example, comparing FIG. 5 with FIG. 8, in the third period t3, the gate of the third transistor T3 receives the low level provided by the first clock terminal ck1. Then the second unit 7 may write a high level into the first intermediate node N01 in response to the first signal, enabling the voltages of both electrodes of the third transistor T3 to be much larger than the gate voltage thereof. The gate-source voltage of the third transistor T3 is much smaller than the threshold voltage thereof. The third transistor T3 is in a completely off state, thereby effectively preventing the third node N3 from the electric leakage to the input terminal In on the path, and thus improving the potential stability of the third node N3.

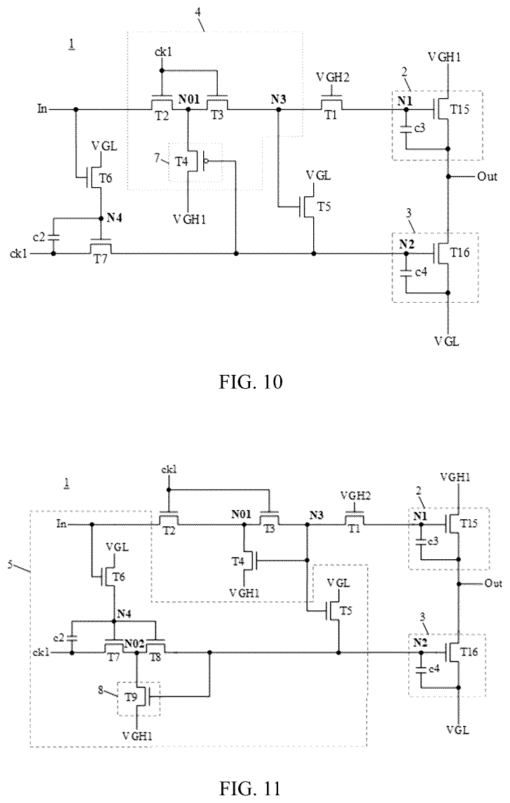

FIG. 9 is a schematic diagram of a circuit structure of the shift unit 1 according to some embodiments of the present disclosure. FIG. 10 is a schematic diagram of a circuit structure of the shift unit 1 according to some embodiments of the present disclosure. Further, referring to the exemplary embodiments illustrated in FIG. 7, FIG. 9 and FIG. 10, the second unit 7 includes a fourth transistor T4, which is electrically connected between the first high potential line VGH1 and the third node N3.

In one exemplary structure, referring to FIG. 7 and FIG. 9, the fourth transistor T4 is an N-type transistor. The gate of the fourth transistor T4 is electrically connected to the third node N3, then the first signal is a signal of the third node N3. Or the gate of the fourth transistor T4 is electrically connected to the first node N1, then the first signal is a signal of the first node N1. Or the gate of the fourth transistor T4 is electrically connected to the output terminal Out, then the first signal is a signal of the output terminal Out.

Referring to the exemplary embodiment in FIG. 8, the level states of the signals of the third node N3, the first node N1 and the output terminal Out are consistent at the same time. When the fourth transistor T4 is the N-type transistor, its gate is connected to any one of the third node N3, the first node N1 and the output terminal Out, and the fourth transistor T4 may be controlled to be turned on in the third period t3, enabling the fourth transistor T4 to write a high level into the first intermediate node N01.

In an embodiment of the present disclosure, such as the exemplary embodiment illustrated in FIG. 9, the gate of the fourth transistor T4 may be electrically connected to the third node N3. On one hand, the type of the fourth transistor T4 is the same as that of the first transistor T1, and all transistors in the shift unit 1 may be the N-type transistors, making the manufacturing process of the circuit simpler. On the other hand, the turned-on state of the fourth transistor T4 is directly controlled by the third node N3. The higher correlation between the fourth transistor T4 and the third node N3 can enhance the anti-leakage capability of the third node N3 to a greater extent.

In another embodiment, referring to FIG. 10, the fourth transistor T4 is the P-type transistor, and a gate of the fourth transistor T4 is electrically connected to the second node N2.

As can be seen in the exemplary embodiment in FIG. 8, at the same time, the level states of the signals of the second node N2 and the third node N3 are opposite. When the fourth transistor T4 is the P-type transistor, its gate is electrically connected to the second node N2, and the fourth transistor T4 may be controlled to be turned on in the third period t3, enabling the fourth transistor T4 to write a high level into the first intermediate node N01.

In addition, in some periods of the fourth period t4, the first clock terminal ck1 provides a high level, the input terminal In provides a low level, and the third node N3 is at a low level. With the two aforementioned designs, the fourth transistor T4 will be turned off under the action of its gate voltage, preventing the fourth transistor T4 from writing a high level into the first node N1 through the turned-on third transistor T3 and thus causing a potential error at the first node N1.

In addition, during at least part of the second period t2, the input terminal In is at a high level, the first clock terminal ck1 is at a high level, and the high level of the input terminal In is written into the third node N3 through the second transistor T2 and the third transistor T3 that are turned on. In this period, the fourth transistor T4 is also turned on and writes a high level to the third node N3. In the first high potential line VGH1 and the second high potential line VGH2, in an embodiment of the present disclosure, the fourth transistor T4 is electrically connected to the first high potential line VGH1. Therefore, the high level voltage written by the fourth transistor T4 to the third node N3 may be the same as the high level voltage of the input terminal In in this part of period. The third node N3 receives consistent voltages from the two paths, resulting in better stability of the node.

In some embodiments, referring to FIG. 4 and FIG. 5, the second control module 5 includes a fifth transistor T5, a sixth transistor T6, a seventh transistor T7, and a second capacitor c2. The fifth transistor T5, the sixth transistor T6, and the seventh transistor T7 may all be N-type transistors. The fifth transistor T5 is electrically connected between the low potential line VGL and the second node N2, and a gate of the fifth transistor T5 is electrically connected to the third node N3. The sixth transistor T6 is electrically connected between the low potential line VGL and the fourth node N4, and a gate of the sixth transistor T6 is electrically connected to the input terminal In. The seventh transistor T7 is electrically connected between the first clock terminal ck1 and the second node N2, and a gate of the seventh transistor T7 is electrically connected to the fourth node N4. The second capacitor c2 is electrically connected between the first clock terminal ck1 and the fourth node N4.

In some embodiments, in the first period t1, the third node N3 is at a high level to control the fifth transistor T5 to be turned on. The fifth transistor T5 writes the low level of the low potential line VGL into the first node N1. Meanwhile, the input terminal In provides a high level to control the sixth transistor T6 to be turned on, and the sixth transistor T6 writes the low level of the low potential line VGL into the fourth node N4, enabling the seventh transistor T7 to be turned off under the action of the low level of the fourth node N4.

In the second period t2 and the third period t3, the third node N3 maintains a high level, and the fifth transistor T5 continuously writes a low level into the first node N1.

In the fourth period t4, the third node N3 is at a low level, and the fifth transistor T5 is turned off. The input terminal In provides a low level. The sixth transistor T6 is turned off and stops to write the low level into the fourth node N4. In this period, when the first clock terminal ck1 is at a high level, under the action of the second capacitor c2, the potential of the fourth node N4 is raised up to a high level, the seventh transistor T7 is controlled to be turned on, and the high level of the first clock terminal ck1 is written into the first node N1, making the second output module 3 output a low level to the output terminal Out in response to the high level of the first node N1. When the signal of the first clock terminal ck1 jumps to a low level, the second capacitor c2 pulls down the potential coupling of the fourth node N4 to a low level, the seventh transistor T7 is turned off, the first node N1 maintains a high level, and the output terminal Out continuously outputs a low level.

FIG. 11 is a schematic diagram of a circuit structure of the shift unit 1 according to some embodiments of the present disclosure. In some embodiments, such as the embodiment shown in FIG. 11, the seventh transistor T7 is electrically connected to the second node N2 through an eighth transistor T8. The eighth transistor T8 may be the N-type transistor. A gate of the eighth transistor T8 is connected to a gate of the seventh transistor T7. A second intermediate node N02 is provided between the seventh transistor T7 and the eighth transistor T8.

In some embodiments, the second control module 5 further includes a third unit 8. The third unit 8 writes a high level into the second intermediate node N02 in response to the second signal. The eighth transistor T8 and the third unit 8 may be configured to prevent electric leakage of the second node N2. During a period in which the second node N2 is at a high level, the third unit 8 may write a high level into the second intermediate node N02 in response to the second signal, causing the gate-source voltage of the eighth transistor T8 to be less than the threshold voltage and completely turning off the eighth transistor T8, thereby preventing the second node N2 from leaking electricity to the first clock terminal ck1 on the path, and thus enabling the second output module 3 to output a low level stably.

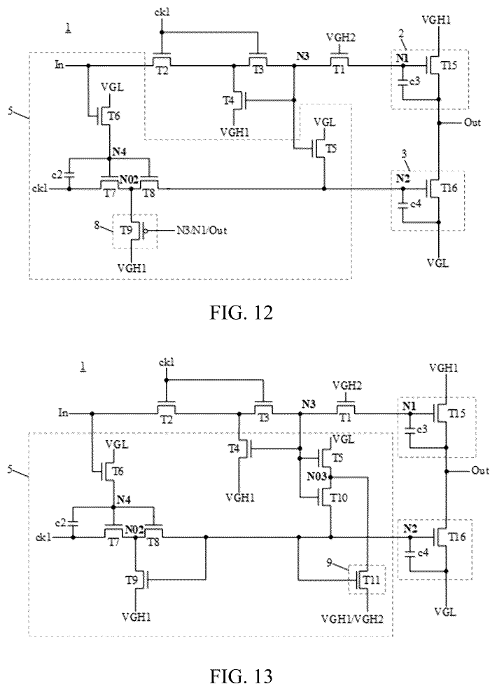

FIG. 12 is a schematic diagram of a circuit structure of the shift unit 1 according to some embodiments of the present disclosure. Further, referring to the exemplary embodiments illustrated in FIG. 11 and FIG. 12, the third unit 8 includes a ninth transistor T9. The ninth transistor T9 is electrically connected between the first high potential line VGH1 and the second intermediate node N02.

In the exemplary embodiment illustrated FIG. 11, the ninth transistor T9 is an N-type transistor, and a gate of the ninth transistor T9 is electrically connected to the second node N2. Then the second signal is a signal of the second node N2.

In this embodiment, the type of the ninth transistor T9 is the same as that of the first transistor T1, and all transistors in the shift unit 1 may be the N-type transistors, making the manufacturing process of the circuit simpler. On the other hand, the turned-on state of the ninth transistor T9 is directly controlled by the second node N2. The higher correlation between the ninth transistor T9 and the second node N2 can enhance the anti-leakage capability of the second node N2 to a greater extent.

In to the exemplary embodiment illustrated in FIG. 12, the ninth transistor T9 is the P-type transistor. The gate of the ninth transistor T9 is electrically connected to the third node N3, then the second signal is a signal of the third node N3. In another embodiment, the gate of the ninth transistor T9 is electrically connected to the first node N1, then the second signal is a signal of the first node N1. In another embodiment, the gate of the ninth transistor T9 is electrically connected to the output terminal Out, then the second signal is a signal of the output terminal Out.

As can be seen in the embodiment illustrated in FIG. 8, at the same time, the level states of the signals of the third node N3, the first node N1 and the output terminal Out and the second node N2 are opposite. When the ninth transistor T9 is the P-type transistor, the gate of the ninth transistor T9 is connected to any one of the third node N3, the first node N1, and the output terminal Out, and the ninth transistor T9 may be controlled to be turned on within a period in which the second node N2 is at a high level, and a high level is written to the second intermediate node N02 by using the ninth transistor T9.

FIG. 13 is a schematic diagram of a circuit structure of the shift unit 1 according to some embodiments of the present disclosure. In some embodiments, such as the embodiment illustrated in FIG. 13, the fifth transistor T5 is electrically connected to the second node N2 through a tenth transistor T10. The tenth transistor T10 may be the N-type transistor. A gate of the tenth transistor T10 is electrically connected to a gate of the fifth transistor T5. A third intermediate node N03 is provided between the fifth transistor T5 and the tenth transistor T10.

The second control module 5 may further include a fourth unit 9. The fourth unit 9 writes a high level to the third intermediate node N03 in response to the third signal.

The tenth transistor T10 and the fourth unit 9 may be configured to prevent electric leakage of the second node N2. During the period when the second node N2 is at a high level, the fourth unit 9 may be turned on in response to the third signal and write a high level to the third intermediate node N03, causing the gate-source voltage of the tenth transistor T10 to be less than the threshold voltage thereof and completely turning off the tenth transistor T10, thereby preventing the second node N2 from leaking electricity towards the low potential line VGL on the path, and thus enabling the second output module 3 to output a low level stably.

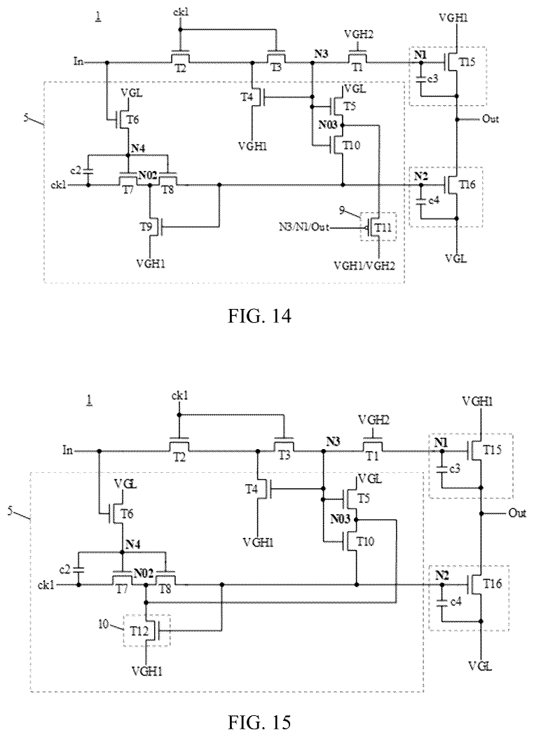

FIG. 14 is a schematic diagram of a circuit structure of the shift unit 1 according to some embodiments of the present disclosure. Further, referring to the exemplary embodiments in FIG. 13 and FIG. 14, the fourth unit 9 includes an eleventh transistor T11. One electrode of the eleventh transistor T11 is electrically connected to the first high potential line VGH1 or the second high potential line VGH2, while the other electrode of the eleventh transistor T11 is electrically connected to the third intermediate node N03.

In some embodiments, such as the exemplary embodiment illustrated in FIG. 13, the eleventh transistor T11 is the N-type transistor, and a gate of the eleventh transistor T11 is electrically connected to the second node N2. Then the third signal is a signal of the second node N2.

In this structure, the type of the eleventh transistor T11 is the same as that of the first transistor T1, and all transistors in the shift unit 1 may be the N-type transistors, making the manufacturing process of the circuit simpler. On the other hand, the turned-on state of the eleventh transistor T11 is directly controlled by the second node N2. The higher correlation between the eleventh transistor T11 and the second node N2 can enhance the anti-leakage capability of the second node N2 to a greater extent.

In another exemplary embodiment, such as the embodiment illustrated in FIG. 14, the eleventh transistor T11 is the P-type transistor. The gate of the eleventh transistor T11 is electrically connected to the third node N3, then the third signal is a signal of the third node N3. In an embodiment, the gate of the eleventh transistor T11 is electrically connected to the first node N1, then the third signal is a signal of the first node N1. In an embodiment, the gate of the eleventh transistor T11 is electrically connected to the third node N3, then the third signal is a signal of the output terminal Out.

According to the embodiment illustrated in FIG. 8, at the same time, the level states of the signals of the third node N3, the first node N1 and the output terminal Out and the second node N2 are opposite. When the eleventh transistor T11 is the P-type transistor, the gate of the eleventh transistor T11 is electrically connected to any one of the third node N3, the first node N1, and the output terminal Out, and the eleventh transistor T11 may be controlled to be turned on within a period in which the second node N2 is at a high level, and a high level is written to the third intermediate node N03 by using the eleventh transistor T11.

In addition, in some embodiments of the present disclosure, the eleventh transistor T11 is electrically connected to the first high potential line VGH1 or the second high potential line VGH2.

As such, in some embodiments, the voltage value of the second high potential signal provided by the second high potential line VGH2 is less than the voltage value of the first high potential signal provided by the first high potential line VGH1. However, the eleventh transistor T11 is connected to the second high potential line VGH2, which can also achieve a good anti-leakage effect. The gate of the tenth transistor T10 is electrically connected to the third node N3. Referring to FIG. 8, at the same time, the level states of the signals of the third node N3 and the second node N2 are opposite. That is, when the second node N2 is at a high level, the third node N3 is at a low level, that is, the gate of the tenth transistor T10 is at a low level. Then, even if the eleventh transistor T11 is electrically connected to the second high potential line VGH2 and writes the second high potential signal into the third intermediate node N03, it can still ensure that the tenth transistor T10 is completely turned off, thereby preventing the second node N2 from leaking electricity through this path.

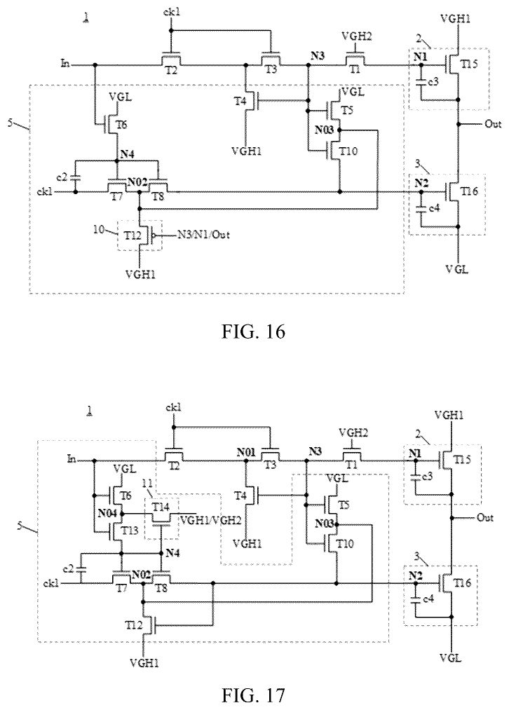

FIG. 15 is a schematic diagram of still a circuit structure of a shift unit 1 according to some embodiments of the present disclosure. FIG. 16 is a schematic diagram of a circuit structure of the shift unit 1 according to some embodiments of the present disclosure. In some embodiments, such as the exemplary embodiment illustrated shown in FIG. 15 and FIG. 16, the seventh transistor T7 is electrically connected to the second node N2 through an eighth transistor T8. The eighth transistor T8 may be the N-type transistor. A gate of the eighth transistor T8 is connected to a gate of the seventh transistor T7. A second intermediate node N02 is provided between the seventh transistor T7 and the eighth transistor T8.

In some embodiments, the fifth transistor T5 is electrically connected to the second node N2 through a tenth transistor T10. The tenth transistor T10 may be the N-type transistor. A gate of the tenth transistor T10 is electrically connected to a gate of the fifth transistor T5. A third intermediate node N03 is provided between the fifth transistor T5 and the tenth transistor T10.

The second control module 5 may further include a fifth unit 10. The fifth unit 10 writes a high level to the second intermediate node N02 and the third intermediate node N03 in response to the fourth signal. During a period in which the second node N2 is at a high level, the fifth unit 10 may write a high level into the second intermediate node N02 and the third intermediate node N03 in response to the fourth signal, making the eighth transistor T8 and the tenth transistor T10 to be completely turned off, thereby preventing the second node N2 from leaking electricity to the first clock terminal ck1 on the path of the eighth transistor T8, and preventing the second node N2 from leaking electricity to the low potential line VGL on the path of the tenth transistor T10, and making the second node N2 more stable, and thus enabling the output terminal Out to output a low level stably.

Further, referring to the exemplary embodiments illustrated in FIG. 15 and FIG. 16, the fifth unit 10 includes a twelfth transistor T12. One electrode of the twelfth transistor T12 is electrically connected to the first high potential line VGH1, and the other electrode of the twelfth transistor T12 is electrically connected to the second intermediate node N02 and the third intermediate node N03.

In one embodiment, referring to FIG. 15, the twelfth transistor T12 is the N-type transistor, and a gate of the twelfth transistor T12 is electrically connected to the second node N2. Then the aforementioned fourth signal is a signal of the second node N2.

In this embodiment, the type of the twelfth transistor T12 is the same as that of the first transistor T1, and all transistors in the shift unit 1 may be the N-type transistors, making the manufacturing process of the circuit simpler. On the other hand, the turned-on state of the twelfth transistor T12 is directly controlled by the second node N2. The higher correlation between the twelfth transistor T12 and the second node N2 can enhance the anti-leakage capability of the second node N2 to a greater extent.

In another embodiment, referring to FIG. 16, the twelfth transistor T12 is a P-type transistor. The gate of the twelfth transistor T12 is electrically connected to the third node N3, then the second signal is a signal of the third node N3. In another embodiment, the gate of the twelfth transistor T12 is electrically connected to the first node N1, then the second signal is a signal of the first node N1. In another embodiment, the gate of the twelfth transistor T12 is electrically connected to the output terminal Out, then the second signal is a signal of the output terminal Out.

As can be seen in the exemplary embodiment illustrated in FIG. 8, at the same time, the level states of the signals of the third node N3, the first node N1 and the output terminal Out and the second node N2 are opposite. When the twelfth transistor T12 is the P-type transistor, the gate of the twelfth transistor T12 is connected to any one of the third node N3, the first node N1, and the output terminal Out, and the twelfth transistor T12 may be controlled to be turned on within a period in which the second node N2 is at a high level, and a high level is written to the second intermediate node N02 and the third intermediate node N03 by using the ninth transistor T9.

All above structures may use the single twelfth transistor T12 to simultaneously write high levels to the second intermediate node N02 and the third intermediate node N03, resulting in a simpler circuit structure.

FIG. 17 is a schematic diagram of a circuit structure of the shift unit 1 according to some embodiments of the present disclosure. In some embodiments, such as the embodiment illustrated in FIG. 17, the sixth transistor T6 is electrically connected to the fourth node N4 through a thirteenth transistor T13. The thirteenth transistor T13 may be the N-type transistor. A gate of the thirteenth transistor T13 is electrically connected to a gate of the sixth transistor T6. A fourth intermediate node N04 is provided between the sixth transistor T6 and the thirteenth transistor T13.

In some embodiments, he second control module 5 further includes a sixth unit 11, which writes a high level to the fourth intermediate node N04 in response to the fifth signal. The thirteenth transistor T13 and the sixth unit 11 are configured to prevent electric leakage of the second node N2. During the period in which the fourth node N4 is at the high level, the sixth unit 11 may write the high level into the fourth intermediate node N04 in response to the fifth signal, causing the gate-source voltage of the sixth unit 11 to be less than the threshold voltage thereof and completely turning off the sixth unit 11, thereby effectively preventing the fourth node N4 from leaking electricity to the low potential line VGL on the path, and thus improving the signal stability of the fourth node N4.

Further, referring to the exemplary embodiment illustrated in FIG. 17, the sixth unit 11 includes a fourteenth transistor T14. One electrode of the fourteenth transistor T14 is electrically connected to the first high potential line VGH1 or the second high potential line VGH2, and the other electrode of the fourteenth transistor T14 is electrically connected to the fourth intermediate node N04.

In some embodiments, the fourteenth transistor T14 is the N-type transistor, and a gate of the fourteenth transistor T14 is electrically connected to the fourth node N4. Then the aforementioned fifth signal is a signal of the fourth node N4.

In this embodiment, the type of the fourteenth transistor T14 is the same as that of the first transistor T1, and all transistors in the shift unit 1 may be the N-type transistors, making the manufacturing process of the circuit simpler. On the other hand, the turned-on state of the fourteenth transistor T14 is directly controlled by the fourth node N4. The higher correlation between the fourteenth transistor T14 and the fourth node N4 can enhance the anti-leakage capability of the fourth node N4 to a greater extent.

In addition, the fourteenth transistor T14 may be electrically connected to the first high potential line VGH1 or the second high potential line VGH2.

As such, in some embodiments, the voltage value of the second high potential signal provided by the second high potential line VGH2 is less than the voltage value of the first high potential signal provided by the first high potential line VGH1. However, the fourteenth transistor T14 is connected to the second high potential line VGH2, which can also achieve a good anti-leakage effect. The gate of the thirteenth transistor T13 is electrically connected to the input terminal In. Referring to FIG. 8, when the fourth node N4 is at a high level, the input terminal In is always at a low level. That is, the gate of the thirteenth transistor T13 is at a low level. Then even if the fourteenth transistor T14 is electrically connected to the second high potential line VGH2 and writes the second high potential signal into the fourth intermediate node N04, it can still ensure that the thirteenth transistor T13 is completely turned off, preventing the fourth node N4 from leaking electricity through this path.

In some embodiments, such as the embodiments illustrated in FIG. 4 and FIG. 5, the first output module 2 includes a fifteenth transistor T15 and a third capacitor c3.

The fifteenth transistor T15 may be the N-type transistor. In some embodiments, the fifteenth transistor T15 is electrically connected between the first high potential line VGH1 and the output terminal Out, and a gate of the fifteenth transistor T15 is electrically connected to the first node N1. The fifteenth transistor T15 is turned on when the first node N1 is at a high level and writes the high level of the first high level line VGH1 into the output terminal Out.

In some embodiments, the third capacitor c3 is electrically connected between the first node N1 and the output terminal Out. When the signal of the output terminal Out jumps from a low level to a high level, the potential of the first node N1 is pulled higher due to the coupling effect of the third capacitor c3, ensuring that the fifteenth transistor T15 is turned on more completely.

The second output module 3 includes a sixteenth transistor T16 and a fourth capacitor c4.

The sixteenth transistor T16 may be the N-type transistor. In some embodiments, the sixteenth transistor T16 is electrically connected between the low potential line VGL and the output terminal Out, and a gate of the sixteenth transistor T16 is electrically connected to the second node N2. The sixteenth transistor T16 is turned on when the second node N2 is at a high level, and writes the low level of the low level line VGL into the output terminal Out.

The fourth capacitor c4 may be electrically connected between the second node N2 and the low potential line VGL for stabilizing the potential of the second node N2.

In some embodiments, the shift unit 1 includes a plurality of transistors. The plurality of transistors are all N-type transistors, for example, indium gallium zinc oxide (IGZO) transistors.

In some embodiments, such as the exemplary embodiment illustrated in FIG. 13, the plurality of transistors include a first transistor T1-eleventh transistor T11 and a thirteenth transistor T13-sixteenth transistor T16, and these transistors are all N-type transistors. Alternatively, referring to FIG. 17, the plurality of transistors include a first transistor T1-eighth transistor T8, a tenth transistor T10, and a twelfth transistor T12-sixteenth transistor T16, and these transistors are all N-type transistors.

In some embodiments, each transistor in the shift unit 1 has a same type, simplifying the layer manufacturing process. Moreover, the N-type transistor has stronger device driving capability, achieving better circuit performance.

In some embodiments, the shift unit 1 includes a plurality of transistors. Some of the transistors are N-type transistors, such as the IGZO transistors, and some of the transistors are P-type transistors, such as Low Temperature Poly-Silicon (LTPS) transistors.

In some embodiments, referring to FIG. 10, FIG. 12, FIG. 14 and FIG. 16, in the shift unit 1, the fourth transistor T4, the ninth transistor T9, the eleventh transistor T11 and/or the twelfth transistor T12 are the P-type transistors, and the other transistors are the N-type transistors.

In some embodiments, two types of transistors are included, allowing for a more flexible connection manner for the gate of transistor. For example, referring to FIG. 16, when the twelfth transistor T12 is the P-type transistor, the gate of the twelfth transistor T12 may be selectively connected to one of the plurality of nodes, providing greater flexibility in the circuit design.

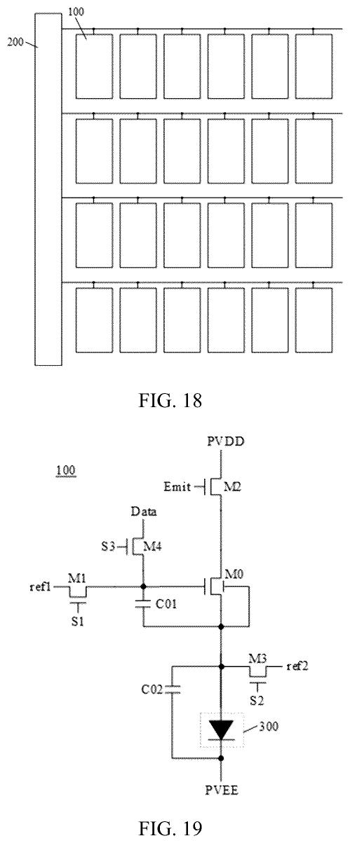

FIG. 18 is a structural schematic diagram of a display panel according to some embodiments of the present disclosure. Based on the same inventive concept, an embodiment of the present disclosure further provides a display panel. As shown in FIG. 18, the display panel includes a pixel circuit 100 and at least one shift register 200. The shift register 200 is electrically connected to the pixel circuit 100.

In combination with the foregoing analysis, in the display panel provided by the embodiments of the present disclosure, since the signal output by the shift register 200 is more stable, the operational reliability of the pixel circuit 100 is higher, and the display panel may have better display effect.

In some embodiments, to improve the residual image and reduce the cost, all transistors in the pixel circuit 100 may all be designed as N-type transistors.

In some embodiments, the pixel circuit 100 includes a driving transistor, a first reset transistor for resetting the gate of the driving transistor, a second reset transistor for resetting the anode of the light-emitting element, a data writing transistor for charging the gate of the driving transistor, and a light-emitting control transistor for controlling light-emitting. These transistors may all be N-type transistors, meaning the effective levels of the driving signals required by these transistors are all high levels.

Among these transistors, the driving logic between the high level output and the clock control signal is similar for the driving signals corresponding to the first reset transistor, the second reset transistor, and the light-emission control transistor. Therefore, in an embodiment of the present disclosure, at least one of the first reset transistor, the second reset transistor and the light-emitting control transistor may be electrically connected to the shift register 200 provided by the embodiments of the present disclosure.

In some embodiments of the present disclosure, the pixel circuit 100 may have various circuit structures. FIG. 19 is a schematic diagram of a circuit structure of a pixel circuit according to some embodiments of the present disclosure. An exemplary circuit structure is shown in FIG. 19, and the pixel circuit includes a driving transistor M0, a first reset transistor M1, a light-emitting control transistor M2, a second reset transistor M3, a data writing transistor M4, a capacitor C01, and a capacitor C02.

In some embodiments, the first reset transistor M1 has a gate electrically connected to the first scan line S1, a first electrode electrically connected to the first reset line ref1, and a second electrode electrically connected to the gate of the driving transistor M0. The first reset transistor M1 is configured to write the signal of the first reset line ref1 into the gate of the driving transistor M0 in response to the high level in the signal provided by the first scan line S1.

In some embodiments, the light-emitting control transistor M2 has a gate electrically connected to the light-emitting control line Emit, a first electrode electrically connected to the power line PVDD, and a second electrode electrically connected to the first electrode of the driving transistor M0. The light-emitting control transistor M2 writes the signal of the power line PVDD into the first electrode of the driving transistor M0 in response to the high level in the signal provided by the light-emitting control line Emit.

In some embodiments, the second reset transistor M3 has a gate electrically connected to the second scan line S2, a first electrode electrically connected to the second reset line ref2, and a second electrode electrically connected to the anode of the light-emitting element 300. The second reset transistor M3 writes the signal of the second reset line ref2 into the anode of the light-emitting element 300 in response to the high level in the signal provided by the second scan line S2.

In some embodiments, the data writing transistor M4 has a gate electrically connected to the third scan line S3, a first electrode electrically connected to the data line Data, and a second electrode electrically connected to the gate of the driving transistor M0. The data writing transistor M4 writes the signal of the data line Data into the gate of the driving transistor M0 in response to the high level in the signal provided by the third scan line S3.

The capacitor C01 may be electrically connected between the gate of the driving transistor M0 and the second electrode of the driving transistor M0. The capacitor C02 may be electrically connected between the second electrode of the driving transistor M0 and a cathode of the light-emitting element 300.

The driving transistor M0 may include only one gate, or may include a top gate and a bottom gate. When the driving transistor M0 includes the top gate and the bottom gate. The gate of the driving transistor M0 mentioned above is understood as the top gate of the driving transistor M0, and further, the bottom gate of the driving transistor M0 may be electrically connected to the second electrode of the driving transistor M0.

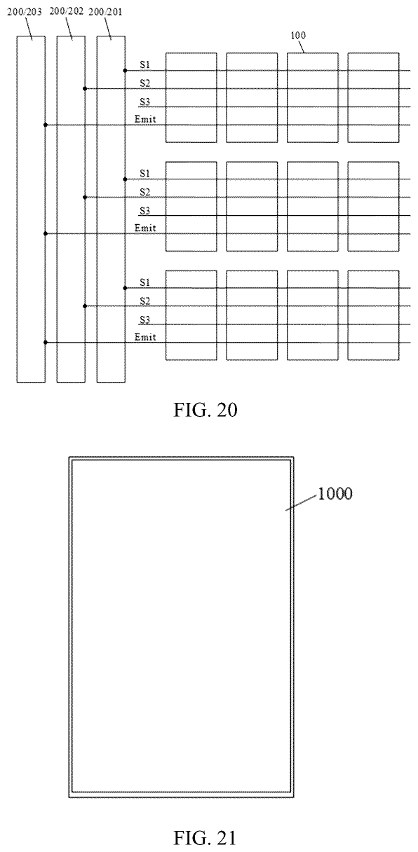

FIG. 20 is a structural schematic diagram of a display panel according to some embodiments of the present disclosure. According to the exemplary embodiment illustrated in FIG. 20, the first scan line S1 is electrically connected to the first shift register 201, the second scan line S2 is electrically connected to the second shift register 202, and the light-emitting control line Emit is electrically connected to the third shift register 203.

In some embodiments, the shift register 200 includes at least one of the first shift register 201, the second shift register 202 and the third shift register 203, making the first scan signal, the light-emitting control signal and/or the second scan signal received by the pixel circuit 100 more stable, and thus enabling the pixel circuit 100 to perform operations such as reset and light-emitting control more reliably.

According to the exemplary embodiment shown in FIG. 20, the first shift register 201, the second shift register 202, and the third shift register 203 are only schematically illustrated on a single side of the pixel circuit 100, and these shift registers 200 may also be located on two opposite sides of the pixel circuit 100. In addition, the third scan line S3 may be connected to other types of shift registers, enabling the pixel circuit 100 to receive the third scan signal.

Based on the same inventive concept, embodiments of the present disclosure further provide a display apparatus. As shown in FIG. 21, which is a structural schematic diagram of a display apparatus provided by an embodiment of the present disclosure, the display apparatus includes the above display panel 1000. The display apparatus shown in FIG. 21 is merely illustrative, and the display apparatus may be any electronic device having a display function such as a mobile phone, a tablet computer, a laptop computer, an e-book, and a television.

The above are merely exemplary embodiments of the present disclosure, which, as mentioned above, are not used to limit the present disclosure. Whatever within the principles of the present disclosure, including any modification, equivalent substitution, improvement, etc., shall fall into the protection scope of the present disclosure.

Finally, it should be understood that the technical solutions of the present disclosure are illustrated by the above embodiments, but not intended to limit thereto. Although the present disclosure has been described in detail with reference to the foregoing embodiments, those skilled in the art can understand that the present disclosure is not limited to the specific embodiments described herein, and can make various modifications, readjustments, and substitutions without departing from the scope of the present disclosure.

What is claimed is:

1. A shift register, comprising a plurality of cascaded shift units that is configured to output a driving signal with an effective level being a high level;
wherein one of the plurality of cascaded shift units comprises:
a first output module, configured to write a signal of a first high potential line into an output terminal when a first node is at a high level;
a second output module, configured to write a signal of a low potential line into the output terminal when a second node is at a high level;
a first control module, configured to write a signal to the first node; and
a second control module, configured to write a signal to the second node;
wherein the first control module comprises a first unit and a first transistor, the first unit is configured to write a signal of an input terminal into a third node in response to a signal provided by a first clock terminal, the first transistor is electrically connected between the third node and the first node, and a gate of the first transistor is electrically connected to a second high potential line; and wherein the second high potential line provides a second high potential signal, and a voltage value of the second high potential signal is smaller than a voltage value of a high level in a signal provided by the input terminal.

2. The shift register according to claim 1, wherein the voltage value of the second high potential signal is v₁, and the voltage value of the high level in the signal provided by the input terminal is v₂, 1V≤v₂−v₁≤3V.

3. The shift register according to claim 1, wherein one of the plurality of cascaded shift units further comprises a first capacitor, a first terminal of the first capacitor is electrically connected to the third node, and a second terminal of the first capacitor receives a fixed potential signal.

4. The shift register according to claim 3, wherein the second terminal of the first capacitor is electrically connected to the low potential line, the first high potential line, or the second high potential line.

5. The shift register according to claim 1, wherein the first unit comprises a second transistor electrically connected between the input terminal and the third node, and a gate of the second transistor is electrically connected to the first clock terminal.

6. The shift register according to claim 5,
wherein the second transistor is electrically connected to the third node through a third transistor, a gate of the third transistor is electrically connected to a gate of the second transistor, and a first intermediate node is provided between the second transistor and the third transistor; and
wherein the first control module further comprises a second unit, and the second unit is configured to write a high level to the first intermediate node in response to a first signal.

7. The shift register according to claim 6,
wherein the second unit comprises a fourth transistor electrically connected between the first high potential line and the third node; and
wherein the fourth transistor is an N-type transistor, and a gate of the fourth transistor is electrically connected to one of the third node, the first node, and the output terminal; or the fourth transistor is a P-type transistor, and a gate of the fourth transistor is electrically connected to the second node.

8. The shift register according to claim 1, wherein the second control module comprises:
a fifth transistor electrically connected between the low potential line and the second node, wherein a gate of the fifth transistor is electrically connected to the third node;
a sixth transistor electrically connected between the low potential line and a fourth node, wherein a gate of the sixth transistor is electrically connected to the input terminal;
a seventh transistor electrically connected between the first clock terminal and the second node, wherein a gate of the seventh transistor is electrically connected to the fourth node; and
a second capacitor electrically connected between the first clock terminal and the fourth node.

9. The shift register according to claim 8,
wherein the seventh transistor is electrically connected to the second node through an eighth transistor, a gate of the eighth transistor is connected to a gate of the seventh transistor, and a second intermediate node is provided between the seventh transistor and the eighth transistor; and
wherein the second control module further comprises a third unit, and the third unit is configured to write a high level to the second intermediate node in response to a second signal.

10. The shift register according to claim 9,
wherein the third unit comprises a ninth transistor electrically connected between the first high potential line and the second intermediate node; and
wherein the ninth transistor is an N-type transistor, and a gate of the ninth transistor is electrically connected to the second node; or the ninth transistor is a P-type transistor, and a gate of the ninth transistor is electrically connected to one of the third node, the first node, and the output terminal.

11. The shift register according to claim 8,
wherein the fifth transistor is electrically connected to the second node through a tenth transistor, a gate of the tenth transistor is electrically connected to a gate of the fifth transistor, and a third intermediate node is provided between the fifth transistor and the tenth transistor; and
wherein the second control module further comprises a fourth unit, and the fourth unit is configured to write a high level to the third intermediate node in response to a third signal.

12. The shift register according to claim 11,
wherein the fourth unit comprises an eleventh transistor, one electrode of the eleventh transistor is electrically connected to the first high potential line or the second high potential line, and another electrode of the eleventh transistor is electrically connected to the third intermediate node; and
wherein the eleventh transistor is an N-type transistor, and a gate of the eleventh transistor is electrically connected to the second node; or the eleventh transistor is a P-type transistor, and a gate of the eleventh transistor is electrically connected to one of the third node, the first node, and the output terminal.

13. The shift register according to claim 8,
wherein the seventh transistor is electrically connected to the second node through an eighth transistor, a gate of the eighth transistor is connected to a gate of the seventh transistor, and a second intermediate node is provided between the seventh transistor and the eighth transistor;
wherein the fifth transistor is electrically connected to the second node through a tenth transistor, a gate of the tenth transistor is electrically connected to a gate of the fifth transistor, and a third intermediate node is provided between the fifth transistor and the tenth transistor; and
wherein the second control module further comprises a fifth unit, and the fifth unit is configured to write a high level to the second intermediate node and the third intermediate node in response to a fourth signal.

14. The shift register according to claim 13,
wherein the fifth unit comprises a twelfth transistor, one electrode of the twelfth transistor is electrically connected to the first high potential line, and another electrode of the twelfth transistor is electrically connected to the second intermediate node and the third intermediate node; and
wherein the twelfth transistor is an N-type transistor, and a gate of the twelfth transistor is electrically connected to the second node; or the twelfth transistor is a P-type transistor, and a gate of the twelfth transistor is electrically connected to one of the third node, the first node, and the output terminal.

15. The shift register according to claim 8,
wherein the sixth transistor is electrically connected to the fourth node through a thirteenth transistor, a gate of the thirteenth transistor is electrically connected to a gate of the sixth transistor, and a fourth intermediate node is provided between the sixth transistor and the thirteenth transistor; and
wherein the second control module further comprises a sixth unit, and the sixth unit is configured to write a high level to the fourth intermediate node in response to a fifth signal.

16. The shift register according to claim 15,
wherein the sixth unit comprises a fourteenth transistor, one electrode of the fourteenth transistor is electrically connected to the first high potential line or the second high potential line, and another electrode of the fourteenth transistor is electrically connected to the fourth intermediate node; and
wherein the fourteenth transistor is an N-type transistor, and a gate of the fourteenth transistor is electrically connected to the fourth node.

17. The shift register according to claim 1,
wherein the first output module comprises a fifteenth transistor and a third capacitor, wherein the fifteenth transistor is electrically connected between the first high potential line and the output terminal, a gate of the fifteenth transistor is electrically connected to the first node, and the third capacitor is electrically connected between the first node and the output terminal; and
wherein the second output module comprises a sixteenth transistor and a fourth capacitor, wherein the sixteenth transistor is electrically connected between the low potential line and the output terminal, a gate of the sixteenth transistor is electrically connected to the second node, and the fourth capacitor is electrically connected between the second node and the low potential line.

18. A display panel, comprising:
a pixel circuit; and
at least one shift register electrically connected to the pixel circuit,
wherein one of the at least one shift register comprises a plurality of cascaded shift units that is configured to output a driving signal with an effective level being a high level;
wherein one of the plurality of cascaded shift units comprises:
a first output module, configured to write a signal of a first high potential line into an output terminal when a first node is at a high level;
a second output module, configured to write a signal of a low potential line into the output terminal when a second node is at a high level;
a first control module, configured to write a signal to the first node;
a second control module, configured to write a signal to the second node;
wherein the first control module comprises a first unit and a first transistor; the first unit is configured to write a signal of an input terminal into a third node in response to a signal provided by a first clock terminal; the first transistor is electrically connected between the third node and the first node, and a gate of the first transistor is electrically connected to a second high potential line, and wherein the second high potential line provides a second high potential signal, and a voltage value of the second high potential signal is smaller than a voltage value of a high level in a signal provided by the input terminal.

19. The display panel according to claim 18, wherein the pixel circuit comprises:
a driving transistor;
a first reset transistor, configured to write a signal of a first reset line into a gate of the driving transistor in response to a high level in a signal provided by a first scan line;
a light-emitting control transistor, configured to write a signal of a power line into a first electrode of the driving transistor in response to a high level in a signal provided by a light-emitting control line;
a second reset transistor, configured to write a signal of a second reset line into a light-emitting element in response to a high level in a signal provided by a second scan line;
a data writing transistor, configured to write a signal of a data line into the gate of the driving transistor in response to a high level in a signal provided by a third scan line;
wherein the first scan line is electrically connected to a first shift register, the second scan line is electrically connected to a second shift register, and the light-emitting control line is electrically connected to a third shift register; and
the shift register comprises at least one of the first shift register, the second shift register, and the third shift register.

20. A display apparatus, comprising a display panel, wherein the display panel comprises a pixel circuit; and at least one shift register electrically connected to the pixel circuit,
wherein one of the at least one shift register comprises a plurality of cascaded shift units that is configured to output a driving signal with an effective level being a high level ;
wherein one of the plurality of cascaded shift units comprises:
a first output module, configured to write a signal of a first high potential line into an output terminal when a first node is at a high level;
a second output module, configured to write a signal of a low potential line into the output terminal when a second node is at a high level;
a first control module, configured to write a signal to the first node;
a second control module, configured to write a signal to the second node; and
wherein the first control module comprises a first unit and a first transistor; the first unit is configured to write a signal of an input terminal into a third node in response to a signal provided by a first clock terminal; the first transistor is electrically connected between the third node and the first node, and a gate of the first transistor is electrically connected to a second high potential line, and wherein the second high potential line provides a second high potential signal, and a voltage value of the second high potential signal is smaller than a voltage value of a high level in a signal provided by the input terminal.
